(19) United States
(12) Patent Application Publication
(10) Pub. No.: US 2009/0129526 A1
(43) Pub. Date: May 21, 2009

(54) PHASE-LOCKED LOOP CIRCUIT AND CORRESPONDING CONTROL METHOD

(75) Inventor: YUM-CHENG CHANG, Mission Viejo, CA (US)

Correspondence Address: PCE INDUSTRY, INC.;ATT. Steven Reiss, 458 E. LAMBERT ROAD, FULLERTON, CA, 92835, US

(73) Assignee: FITIPOWER INTEGRATED TECHNOLOGY, INC., Hsinchu (TW)

(21) Appl. No.: 12/192,036

(22) Filed: Aug. 14, 2008

(30) Foreign Application Priority Data
Nov. 15, 2007 (CN) 200710187921.3

(51) Int. Cl. H03D 3/24

(52) U.S. Cl. 375/376

(57) ABSTRACT

A phase-locked loop circuit includes a phase frequency detector, a loop filter, a voltage-controlled oscillator, an N/N+1 times frequency-divider and a controller. The phase frequency detector is configured for receiving a reference frequency and a feedback frequency, and comparing the reference frequency and the feedback frequency to output an adjust signal based on the comparison result. The loop filter is configured for filtering out noise from the adjust signal. The voltage-controlled oscillator is configured for sending an oscillating frequency and adjusting the oscillating frequency based on the adjust signal. The voltage-controlled oscillator, the N/N+1 times frequency-divider and the phase frequency detector composes a feedback loop for sending out the feedback frequency. The controller is configured for controlling the N/N+1 times frequency-divider to divide the oscillating frequency by N during a first period and divide the oscillating frequency by N+1 during a second period for obtain the feedback frequency.

### CROSS-REFERENCE TO RELATED APPLICATIONS

This application claims all benefits accruing under 35 U.S.C. §119 from China Patent Application No. 200710187921.3, filed on Nov. 15, 2007 in the China Intellectual Property Office, the disclosure of which is incorporated herein by reference.

### BACKGROUND

1. Technical Field

The present invention generally relates to a phase-locked loop circuit and a corresponding control method.

2. Description of Related Art

Digital televisions have the advantages of higher definition (or higher resolution) and compact disc (CD) level multi-channel audio output as compared to traditional analog televisions. Nowadays, various countries such as United States, Europe and Japan have already established their own digital television broadcast formats, e.g., vestigial sideband (“VSB”) for the United States. The detailed information with respect to the VSB broadcast format has been published in a paper by Wayne et al. on IEEE Transactions on Consumer Electronics, vol. 41, No. 3 (August 1995), entitled “VSB Modem Subsystem Design for Grand Alliance Digital Television Receivers”, the disclosure of which is fully incorporated herein by reference.

Conventional digital television receivers usually include a phase-locked loop circuit for improving the anti-interference capability thereof. A typical phase-locked loop circuit includes a phase frequency detector (PFD), a loop filter, an N times frequency-divider (N is an integer), and a voltage-controlled oscillator (VCO). The voltage-controlled oscillator is configured for sending out an oscillating frequency. The voltage-controlled oscillator, the N times frequency-divider and the phase frequency detector compose a feedback loop configured for sending out a feedback frequency. The feedback frequency that is fed to the phase frequency detector is 1/N times the output oscillating frequency of the voltage-controlled oscillator. The phase frequency detector compares the feedback frequency and a reference frequency. If the feedback frequency is not the same as the reference frequency, the phase frequency detector sends out an adjust signal for adjusting the output oscillating frequency of the voltage-controlled oscillator. The typical phase-locked loop circuit forces the oscillating frequency to be exactly N times the reference frequency.

The oscillating frequency of the voltage-controlled oscillator is greatly limited by the reference frequency, and cannot be varied in steps any smaller than that of the reference frequency, thus greatly limiting the use of the phase-locked loop circuit.

Therefore, what is needed is a phase-locked loop circuit and a method that can solve the above problem.

### SUMMARY

A phase-locked loop circuit in accordance with a present embodiment is provided. The phase-locked loop circuit includes a phase frequency detector, a loop filter, a voltage-controlled oscillator, an N/N+1 times frequency-divider and a controller. The phase frequency detector is configured for receiving a reference frequency and a feedback frequency, and comparing the reference frequency and the feedback frequency to output an adjust signal based on the comparison result. The loop filter is configured for filtering out noise from the adjust signal. The voltage-controlled oscillator is configured for sending out an oscillating frequency and adjusting the oscillating frequency based on the adjust signal. The N/N+1 times frequency-divider is arranged between the voltage-controlled oscillator and the phase frequency detector. The voltage-controlled oscillator, the N/N+1 times frequency-divider and the phase frequency detector composes a feedback loop for sending out the feedback frequency. The controller is configured for controlling the N/N+1 times frequency-divider to divide the oscillating frequency by N during a first period and divide the oscillating frequency by N+1 during a second period to obtain the feedback frequency.

A control method for the phase-locked loop circuit in accordance with another present embodiment is also provided. The control method includes:
step A: achieving the oscillating frequency sent out by the voltage-controlled oscillator;
step B: obtaining a ratio between the oscillating frequency and the reference frequency, and processing the ratio to obtain an integral signal and a fractional signal;
step C: processing the integral signal to obtain a first process signal p and a second process signal a;
step D: comparing the second process signal a with a predetermined minimum value Min, and adjusting the first process signal p and the second process signal a to obtain a first adjusted signal p_{adjust} and a second adjusted signal a_{adjust};
step E: randomizing the fractional signal to obtain a randomized signal xin;
step F: adding the randomized signal xin into the second adjusted signal a_{adjust} to obtain a second interim signal a_{adjust}′, and using the first adjust signal p_{adjust} as a first interim signal p_{adjust}′;
step G: processing the first interim signal p_{adjust}′ and the second interim signal a_{adjust}′ to obtain a first final signal p_{final} and a second final signal a_{final}; and
step H: calculating the first period and the second period by using the first final signal p_{final}, the second final signal a_{final} and the minimum value Min, and controlling the N/N+1 times frequency-divider to divide the oscillating frequency by N during the first period and divide the oscillating frequency by N+1 during the second period.

Other advantages and novel features will become more apparent from the following detailed description of embodiments, when taken in conjunction with the accompanying drawings.

### BRIEF DESCRIPTION OF THE DRAWINGS

Many aspects of the present phase-locked loop circuit can be better understood with reference to the following drawings. The components in the drawings are not necessarily drawn to scale, the emphasis instead being placed upon clearly illustrating the principles of the present phase-locked loop circuit. Moreover, in the drawings, like reference numerals designate corresponding parts throughout the several views.

FIG. 1 is a functional block diagram of a phase-locked loop circuit in accordance with a present embodiment.

FIG. 2 is a flow chart of a control method for the phase-locked loop circuit of FIG. 1.

### DETAILED DESCRIPTION

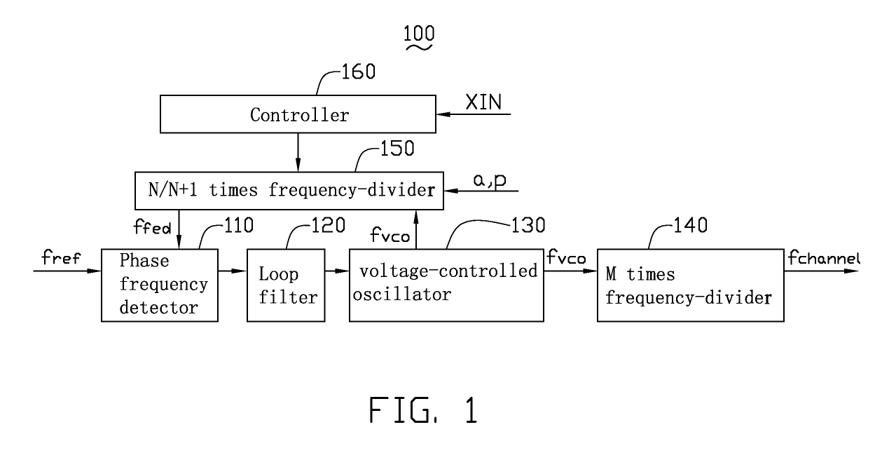

Referring to FIG. 1, a phase-locked loop circuit 100 adapted to a digital television receiver, in accordance with a present embodiment, is provided. The phase-locked circuit 100 includes a phase frequency detector 110, a loop filter 120 electrically connected to the phase frequency detector 110, a voltage-controlled oscillator 130 electrically connected to the loop filter 120, an N/N+1 times frequency-divider 150 electrically connected to the voltage-controlled oscillator 130 and the phase frequency detector 110, and a controller 160 electrically connected to the N/N+1 times frequency-divider 150.

The voltage-controlled oscillator 130, the N/N+1 times frequency-divider 150 and the phase frequency detector 110 compose a feedback loop for sending out a feedback frequency f_{fed} to the phase frequency detector 110. The phase frequency detector 110 is configured for receiving a reference frequency f_{ref} and the feedback frequency f_{fed}, and comparing the reference frequency f_{ref} and the feedback frequency f_{fed} to generate an adjust signal based on the comparison result. The loop filter 120 is configured for receiving the adjust signal and filtering out noise form the adjust signal. The voltage-controlled oscillator 130 is configured for sending out an oscillating frequency f_{vco}, and adjusting the oscillating frequency f_{vco} based on the adjust signal. The N/N+1 times frequency-divider 150 receives a control signal sent by the controller 160, to divide the oscillating frequency f_{vco} by N during a first period T1 and divide the oscillating frequency f_{vco} by N+1 during a second period T2 to obtain the feedback frequency f_{fed}, such that the oscillating frequency f_{vco} is determined from equation 1, which is expressed here:

$${f}_{vco} = \frac{T 1 {Nf}_{fed} + T 2 ( N + 1 ) {f}_{fed}}{T 1 + T 2} \qquad equation 1$$

Furthermore, the present phase-locked loop circuit 100 is used to make the feedback frequency f_{fed} the same as the reference frequency f_{ref}, thus the feedback frequency f_{fed} should be equal to the reference frequency f_{ref}. Therefore, the oscillating frequency f_{vco} may also be determined from equation 2 as follows:

$${f}_{vco} = \frac{T 1 {Nf}_{ref} + T 2 ( N + 1 ) {f}_{ref}}{T 1 + T 2} \qquad equation 2$$

In this exemplary embodiment, the present phase-locked loop circuit 100 further includes a M times frequency-divider 140 electrically connected to the voltage-controlled oscillator 130. The M times frequency-divider 140 receives the oscillating frequency f_{vco} and divides the oscillating frequency f_{vco} by M to obtain a channel frequency f_{channel}, which is the output frequency of the phase-locked loop circuit. In other words, the oscillating frequency f_{vco} is M times the channel frequency f_{channel}, that is, f_{vco}=Mf_{channel}.

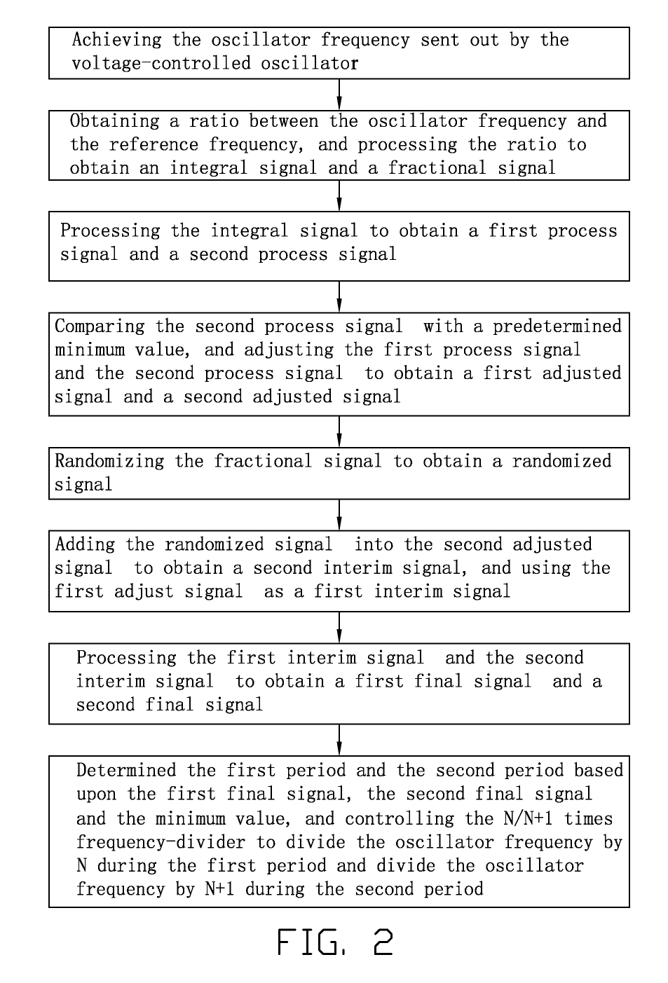

Referring to FIG. 2, a control method for the phase-locked loop circuit 100 is provided. The control method includes following steps:

Step A: setting the oscillating frequency f_{vco} of the voltage-controlled oscillator 130 based on the channel frequency f_{channel}.

In this step, the channel frequency f_{channel} is the needed frequency in practice, therefore, the oscillating frequency f_{vco} may be achieved based upon the channel frequency f_{channel} and the equation f_{vco}=Mf_{channel}.

Step B: obtaining a ratio between the oscillating frequency f_{vco} and the reference frequency f_{ref}, and processing the ratio to obtain an integral signal f_{integer} and a fractional signal f_{fractional}.

In this step, the ratio between the oscillating frequency f_{vco} and the reference frequency f_{ref} is processed by a mode selected from a group consisting of the round function, the floor function and the ceil function. If the ratio is processed by the round function, the integral signal f_{integer} is determined by the equation

$${f}_{integer} = round ( \frac{{f}_{vco}}{{f}_{ref}} ) ,$$

and the fractional signal f_{fractional} is determined by the equation

$${f}_{fractional} = \frac{{f}_{vco}}{{f}_{ref}} - {f}_{integer} ,$$

where the fractional signal f_{fractional} is a positive number or a negative number. If the ratio is processed by the floor function, the integral signal f_{integer} is determined by the equation

$${f}_{integer} = floor ( \frac{{f}_{vco}}{{f}_{ref}} ) ,$$

and the fractional signal f_{fractional} is determined by the equation

$${f}_{fractional} = \frac{{f}_{vco}}{{f}_{ref}} - {f}_{integer} ,$$

where the fractional signal f_{fractional} will be a positive number. If the ratio is processed by the ceil function, the integral signal f_{integer} is determined by the equation

$${f}_{integer} = ceil ( \frac{{f}_{vco}}{{f}_{ref}} ) ,$$

and the fractional signal f_{fractional} is determined by the equation

$${f}_{fractional} = \frac{{f}_{vco}}{{f}_{ref}} - {f}_{integer} ,$$

and the fractional signal f_{factional} will be a negative number. In this exemplary embodiment, the ratio is calculated using the round function.

Step C: processing the integral signal f_{integer} to obtain a first process signal p and a second process signal a.

In this step, the first process signal p and the second process signal a are both obtained by processing the integral signal f_{integer} received in step B. The first process signal p is achieved by the equation

$$p = floor ( \frac{{f}_{integer}}{N} ) ,$$

and the second process signal a is achieved by the equation a=f_{integer}−p·N.

Step D: comparing the second process signal a with a predetermined minimum value Min, and adjusting the first process signal p and the second process signal a to obtain a first adjusted signal p_{adjust} and a second adjusted signal a_{adjust}.

If the second process signal a is very small, it is prone to be filtered out by the phase-locked loop circuit 100. Thus the first process signal p and the second process signal a should be processed to obtain the first adjusted signal p_{adjust} and the second adjusted signal a_{adjust} for avoiding the above problem.

In this step, a predetermined minimum value Min is defined firstly, and the predetermined minimum value Min should be an integral number. Then the second process signal a is compared with the predetermined minimum value Min. If the second signal a is smaller than the predetermined minimum value Min, the first adjusted signal p_{adjust} is achieved by the equation p_{adjust}=p−1, and the second adjusted signal a_{adjust} is achieved by the equation a_{adjust}=a+N; and if the second signal a is larger than the predetermined minimum value Min, the first adjusted signal p_{adjust} is achieved by the equation p_{adjust}=p, and the second adjusted signal a_{adjust} is achieved by the equation a_{adjust}=a.

Step E: randomizing the fractional signal f_{fractional} to obtain a randomized signal xin.

In this step, the randomized signal xin is obtained by processing the fractional signal f_{fractional} through a randomizing process. In the randomizing process the fractional signal f_{fractional} is multiplied by a bit number, such as 2^{bit}; then flooring the product to obtain the randomized signal xin. That is, xin=floor(f_{fractional}·2^{bit}), wherein the bit number 2^{bit} should be a big number, such as 2¹⁶.

Step F: adding the randomized signal xin into the second adjusted signal a_{adjust} to obtain a second interim signal a_{adjust}′, and using the first adjust signal p_{adjust} as a first interim signal p_{adjust}′.

In this step, the randomized signal xin is added into the second adjusted signal a_{adjust} to obtain the second interim signal a_{adjust}′, such that the second interim signal a_{adjust}′ have information related to the fractional signal f_{fractional}. The second interim signal a_{adjust}′ may be expressed by the equation a_{adjust}′=a_{adjust}+xin; and the first interim signal p_{adjust}′ may be expressed by the equation p_{adjust}′=p_{adjust}.

Step G: processing the first interim signal p_{adjust}′ and the second interim signal a_{adjust}′ to obtain a first final signal p_{final} and a second final signal a_{final}.

The step G further includes the following steps:
step g1: comparing the second interim signal a_{adjust}′ with the sum of N and the predetermined minimum value Min; if the second interim signal a_{adjust}′ is larger than the sum of N and the predetermined minimum value Min, adding the first interim signal p_{adjust}′ with 1 and subtracting the second interim signal a_{adjust}′ with N such that p_{adjust}′=p_{adjust}′+1 and a_{adjust}′=a_{adjust}−N, then repeating step g1; if not, proceeding step g2;
step g2: comparing the second interim signal a_{adjust}′ with the predetermined minimum value Min; if the second interim signal a_{adjust}′ is smaller than the predetermined minimum value Min, the first final signal p_{final} being achieved by the equation p_{final}=p_{adjust}−1, and the second final signal a_{final} is achieved by the equation a_{final}=a_{adjust}+N; if not, the first final signal p_{final} will be determined by the equation p_{final}=p_{adjust}, and the second final signal a_{final} will be determined by the equation a_{final}=a_{adjust}.

As shown above, the first final signal p_{final} and the second final signal a_{final} are obtained based upon the first interim signal p_{adjust}′ and the second interim signal a_{adjust}′.

Step H: determining the first period T1 and the second period T2 based on the first final signal p_{final}, the second final signal a_{final} and the minimum value Min, and controlling the N/N+1 times frequency-divider to divide the oscillating frequency f_{vco} by N during the first period T1 and divide the oscillating frequency f_{vco} by N+1 during the second period T2.

In this step, the first period T1 is determined by the difference of the first signal p_{final} with the minimum value Min, and the second period T2 is determined by the second final signal a_{final}. The controller 160 controls the N/N+1 times frequency-divider 150 to divide the oscillating frequency f_{vco} by N during the period T1 and divide the oscillating frequency f_{vco} by N+1 during the second period T2.

The present phase-locked loop circuit 100 employs the N/N+1 times frequency-divider 150 to divide the oscillating frequency f_{vco} by N during the period T1 and divide the oscillating frequency f_{vco} by N+1 during the second period T2. Thus the oscillating frequency f_{vco} may not be an integral number (N) times the reference frequency f_{ref} such that the oscillating frequency f_{vco} will be not limited by the reference frequency f_{ref}. Therefore, the present phase-locked loop circuit 100 have a wider use range.

It is believed that the present embodiments and their advantages will be understood from the foregoing description and it will be apparent that various changes may be made thereto without departing from the spirit and scope of the invention or sacrificing all of its material advantages, the examples hereinbefore described merely being preferred or exemplary embodiments of the present invention.

What is claimed is:

1. A phase-locked loop circuit, comprising:
a phase frequency detector configured for receiving a reference frequency and a feedback frequency, and comparing the reference frequency and the feedback frequency to output an adjust signal based on the comparison result;
a loop filter configured for filtering out noise from the adjust signal;
a voltage-controlled oscillator configured for sending out an oscillating frequency and adjusting the oscillating frequency based on the adjust signal;
a N/N+1 times frequency-divider connected to the voltage-controlled oscillator and the phase frequency detector and forming a feedback loop from the voltage-controlled oscillator to the phase frequency detector;
a controller configured for controlling the N/N+1 times frequency-divider to divide the oscillating frequency by N during a first period and to divide the oscillating frequency by N+1 during a second period for obtain the feedback frequency.

2. The phase-locked loop circuit as claimed in claim 1, further comprising an M times frequency-divider configured for dividing the oscillating frequency by M to obtain a channel frequency.

3. A control method for the phase-locked loop circuit of claim 1, comprising:
step A: achieving the oscillating frequency sent out by the voltage-controlled oscillator;
step B: obtaining a ratio between the oscillating frequency and the reference frequency, and processing the ratio to obtain an integral signal and a fractional signal;
step C: processing the integral signal to obtain a first process signal p and a second process signal a;
step D: comparing the second process signal a with a predetermined minimum value Min, and adjusting the first process signal p and the second process signal a to obtain a first adjusted signal p_{adjust} and a second adjusted signal a_{adjust};
step E: randomizing the fractional signal to obtain a randomized signal xin;
step F: adding the randomized signal xin into the second adjusted signal a_{adjust} to obtain a second interim signal a_{adjust}′, and using the first adjust signal p_{adjust} as a first interim signal p_{adjust}′;
step G: processing the first interim signal p_{adjust}′ and the second interim signal a_{adjust}′ to obtain a first final signal p_{final} and a second final signal a_{final}; and
step H: determined the first period and the second period based upon the first final signal p_{final}, the second final signal a_{final} and the minimum value Min, and controlling the N/N+1 times frequency-divider to divide the oscillating frequency by N during the first period and divide the oscillating frequency by N+1 during the second period.

4. The control method as claimed in claim 3, wherein in the step A, the oscillating frequency is achieved by a channel frequency, which is a needed frequency in practice.

5. The control method as claimed in claim 4, wherein in the step B, the integral signal is obtained by processing the ratio through one mode selected from a group consisting of the round function, the floor function and the ceil function, and the fractional signal is obtained by subtracting the ratio with the integral signal.

6. The control method as claimed in claim 5, wherein in the step C, the first process signal p is obtained by performing the floor function after dividing the integral signal by N, and the second process signal a is obtained by subtracting the integral signal with a product multiplying the first process signal p by N.

7. The control method as claimed in claim 6, wherein in the step D, the predetermined minimum value Min is an integral number, if the second signal a is smaller than the predetermined minimum value Min, the first adjusted signal p_{adjust} is achieved by the equation p_{adjust}=p−1, and the second adjusted signal a_{adjust} is achieved by the equation a_{adjust}=a+N; and if the second signal a is bigger than the predetermined minimum value Min, the first adjusted signal p_{adjust} is achieved by the equation p_{adjust}=p, and the second adjusted signal a_{adjust} is achieved by the equation a_{adjust}=a.

8. The control method as claimed in claim 7, wherein in the step E, the randomized signal xin is obtained by flooring a product of the fractional signal f_{fractional} with a bit number.

9. The control method as claimed in claim 8, wherein the step G further includes:
step g1: comparing the second interim signal a_{adjust}′ with the sum of N and the predetermined minimum value Min; if the second interim signal a_{adjust}′ bigger than the sum, adding the first interim signal p_{adjust}′ with 1 and subtracting the second interim signal a_{adjust}′ with N such that p_{adjust}′=p_{adjust}′+1 and a_{adjust}′=a_{adjust}′−N, then repeating step g1; if not, performing step g2;
step g2: comparing the second interim signal a_{adjust}′ with the predetermined minimum value Min; if the second interim signal a_{adjust}′ smaller than the predetermined minimum value Min, the first final signal p_{final} being achieved by the equation p_{final}=p_{adjust}−1, and the second final signal a_{final} is achieved by the equation a_{final}=a_{adjust}+N; and if not, the first final signal p_{final} being achieved by the equation p_{final}=p_{adjust}, and the second final signal a_{final} being achieved by the equation a_{final}=a_{adjust}.

10. The control method as claimed in claim 9, wherein in the step H, the first period is determined by the difference of the first final signal p_{final} with the minimum value Min, and the second period T2 is determined by the second final signal a_{final}.
